(19) United States
(12) Patent Application Publication
(10) Pub. No.: US 2015/0049546 A1
(43) Pub. Date: Feb. 19, 2015

(54) METHOD OF PROGRAMMING FUSE CELLS AND REPAIRING MEMORY DEVICE USING THE PROGRAMMED FUSE CELLS

(71) Applicant: SAMSUNG ELECTRONICS CO., LTD., Suwon-si (KR)

(72) Inventor: Ahn Choi, Suwon-si (KR)

(21) Appl. No.: 14/306,851

(22) Filed: Jun. 17, 2014

(30) Foreign Application Priority Data
Aug. 14, 2013 (KR) 10-2013-0096342

(51) Int. Cl. G11C 29/00; H01L 23/525; G11C 17/16

(52) U.S. Cl. CPC G11C 29/787; G11C 17/16; H01L 23/5252
USPC 365/185.09; 327/525

(57) ABSTRACT

A plurality of fuse cells includes a first fuse cell and a second fuse cell. Each of the first and second fuse cells includes a first anti-fuse and a second anti-fuse. A method of programming the fuse cells includes rupturing the first anti-fuse of the first fuse cell based on first data loaded to a program control circuit. The method includes rupturing the second anti-fuse of the first fuse cell before loading second data to the program control circuit. The second data is for rupturing the first anti-fuse of the second fuse cell or the second anti-fuse of the second fuse cell.

### CROSS-REFERENCE TO RELATED PATENT APPLICATION

This U.S. Non-provisional application claims priority under 35 U.S.C. §119 to Korean Patent Application No. 10-2013-0096342, filed on Aug. 14, 2013 in the Korean Intellectual Property Office (KIPO), the disclosure of which is incorporated by reference herein in its entirety.

### TECHNICAL FIELD

The present inventive concept relates to electrical fusing, and more particularly to a method of programming fuse cells and repairing a memory device using the programmed fuse cells.

### DISCUSSION OF THE RELATED ART

An anti-fuse includes two electrodes and a dielectric between the two electrodes. The two electrodes are electrically disconnected from each other before the dielectric is ruptured and the two electrodes are electrically connected to each other after the dielectric is ruptured. Each anti-fuse can store a data bit by rupturing the anti-fuse. The dielectric may include silicon dioxide, silicon nitride, or tantalium oxide.

A semiconductor memory device may need a storing unit to store non-volatile data such as fault addresses. For example, the non-volatile data can be stored by programming a plurality of fuse cells including an anti-fuse. Due to an increase in time for programming the fuse cells, the accuracy of programming the fuse cells may decrease and thus the productivity of the semiconductor memory device may be degraded.

### SUMMARY

According to an exemplary embodiment of the present inventive concept, a plurality of fuse cells includes a first fuse cell and a second fuse cell, wherein each of the first and second fuse cells includes a first anti-fuse and a second anti-fuse. A method of programming the fuse cells includes rupturing the first anti-fuse of the first fuse cell based on first data loaded to a program control circuit, rupturing the second anti-fuse of the first fuse cell before loading second data to the program control circuit. The second data is for rupturing the first anti-fuse of the second fuse cell or the second anti-fuse of the second fuse cell.

In an exemplary embodiment of the present inventive concept, a first rupture completion signal may be activated when the rupturing of the first anti-fuse of the first fuse cell is completed.

The rupturing of the second anti-fuse of the first fuse cell may be executed in response to the first rupture completion signal.

Each of the first and second fuse cells may further include a third anti-fuse.

The method may further include rupturing the third anti-fuse of the first fuse cell before loading the second data to the program control circuit to rupture the first anti-fuse of the second fuse cell or the second anti-fuse of the second fuse cell or the third anti-fuse of the second fuse cell.

A second rupture completion signal may be activated when the rupturing of the second anti-fuse of the first fuse cell is completed.

The rupturing of the third anti-fuse may be executed in response to the second rupture completion signal.

The first data and the second data may include fault addresses corresponding to fault memory cells in a normal memory cell array.

The fuse cells may be used to store signatures of the fault memory cells.

The first anti-fuse and the second anti-fuse in each of the first and second fuse cells may have substantially the same rupture voltage level.

The first anti-fuse and the second anti-fuse included in each of the fuse cells may have different rupture voltage levels from each other.

According to an exemplary embodiment of the present inventive concept, a memory device includes a plurality of fuse cells including a first fuse cell and a second fuse cell, wherein each of the first and second fuse cells includes a first anti-fuse and a second anti-fuse. A method of repairing the memory device includes detecting fault addresses corresponding to fault memory cells in a normal memory cell array, rupturing the first anti-fuse of the first fuse cell based on first data loaded to program control circuit. The first data includes at least one first fault address among the fault addresses. The method further includes rupturing the second anti-fuse of the first fuse cell before loading second data to the program control circuit. The second data is for rupturing the first anti-fuse of the second fuse cell or the second anti-fuse of the second fuse cell. The second data includes at least one second fault address among the fault addresses. The method further includes accessing redundant memory cells corresponding to the fault memory cells are accessed when memory access request to the fault addresses is generated during runtime and the first and second anti-fuses of the plurality of fuse cells are ruptured.

According to an exemplary embodiment of the present inventive concept, a fuse circuit is provided. The fuse circuit includes a fuse cell array and a program control circuit. The fuse cell array includes a plurality of fuse row circuits. Each of the fuse row circuits is configured to perform programming on a plurality of fuse cells in each of the fuse row circuits based on the signals provided by the program control circuit. The program control circuit is configured to provide a plurality of signals to the fuse cell array. Each of the fuse cells includes a first anti-fuse and a second anti-fuse. Sequential rupturing of the first and second anti-fuses of the first fuse cell included in the fuse cell array is performed based on first data loaded to the program control circuit before loading second data to the program control circuit. The second data is for rupturing the first or the second anti-fuses of the second fuse cell included in the fuse cell array.

The signals provided by the program control circuit may include a first row selection signal, a first anti-fuse selection signal, a second anti-fuse selection signal, a sense enable signal, or a program signal.

The fuse circuit may further include a sensing unit. The sensing unit may be configured to output a sense output signal based on a program output signal provided by the fuse cell array. The program output signal may include programmed values of the plurality of fuse cells in each of the fuse row circuits.

The fuse cell array may further include a multiplexer. The multiplexer may be configured to select one of outputs from the plurality of fuse row circuits.

Each of the fuse cells may further comprise a first program transistor and a second program transistor. One node of the first anti-fuse and one node of the second anti-fuse may be connected to a first node. The first node may be connected to the driving voltage (VDD) node. The other node of the first anti-fuse may be connected to a source terminal of the first program transistor and the other node of the second anti-fuse may be connected to a source terminal of the second program transistor. A drain terminal of the first program transistor and a drain terminal of the second program transistor may be connected to a second node. The first anti-fuse selection signal may be input to a gate terminal of the first program transistor. The second anti-fuse selection signal may be input to a gate terminal of the second program transistor to control the second program transistor.

Each of the fuse cells may further include a first switch, a second switch, and third switch. One node of the first switch may be connected to the second node and the other node of the first switch may be connected to a third node. One node of the second switch and one node of the third switch may be connected to the third node. The other node of the second switch may be connected to the ground node.

The first anti-fuse may be ruptured based on the first anti-fuse selection signal and the second anti-fuse may be ruptured based on the second anti-fuse selection signal.

The first anti-fuse and the second anti-fuse may be ruptured based on the first row selection signal.

### BRIEF DESCRIPTION OF THE DRAWINGS

The above and other features of the present inventive concept will become more apparent by describing in detail exemplary embodiment thereof with reference to the accompanying drawings of which:

FIG. 1 is a flow chart illustrating a method of programming fuse cells according to an exemplary embodiment of the present inventive concept;

FIG. 2 is a block diagram illustrating a fuse circuit according to an exemplary embodiment of the present inventive concept;

FIG. 3 is a block diagram illustrating a fuse cell array included in the fuse circuit of FIG. 2 according to an exemplary embodiment of the present inventive concept;

FIG. 4 is a block diagram illustrating a first fuse cell row circuit included in the fuse cell array of FIG. 3 according to an exemplary embodiment of the present inventive concept;

FIG. 5 is a block diagram illustrating a fuse cell included in the first fuse cell row circuit of FIG. 4 according to an exemplary embodiment of the present inventive concept;

FIGS. 6A, 6B, 6C, and 6D are timing diagrams illustrating operations of programming a fuse cell by rupturing sequentially a first anti-fuse and a second anti-fuse according to an exemplary embodiment of the present inventive concept;

FIG. 7 is a timing diagram illustrating an operation of programming the first fuse cell row circuit of FIG. 4 according to an exemplary embodiment of the present inventive concept;

FIGS. 8A and 8B are circuit diagrams illustrating anti-fuses included in the fuse cell of FIG. 5 according to an exemplary embodiment of the present inventive concept;

FIG. 9 is a flow chart illustrating a method of programming fuse cells according to an exemplary embodiment of the present inventive concept;

FIG. 10 is a circuit diagram illustrating fuse cells included in the first fuse cell row circuit of FIG. 4 according to an exemplary embodiment of the present inventive concept;

FIG. 11 is a flow chart illustrating a method of repairing a memory device according to an exemplary embodiment of the present inventive concept;

FIG. 12 is a diagram illustrating data which is programmed to the fuse cell array of FIG. 3 according to an exemplary embodiment of the present inventive concept;

FIG. 13 is a diagram illustrating a programming sequence as a comparison example;

FIG. 14 is a diagram illustrating a programming sequence according to an exemplary embodiment of the present inventive concept;

FIGS. 15A and 15B are diagrams illustrating partial programming sequences included in the programming sequence of FIG. 14 according to an exemplary embodiment of the present inventive concept;

FIG. 16 is a block diagram illustrating a semiconductor memory device including the fuse circuit according to an exemplary embodiment of the present inventive concept;

FIG. 17 is a diagram illustrating a mobile system applying the semiconductor memory device according to an exemplary embodiment of the present inventive concept; and

FIG. 18 is a diagram illustrating a computing system applying the semiconductor memory device according to an exemplary embodiment of the present inventive concept.

### DETAILED DESCRIPTION OF THE EMBODIMENTS

Exemplary embodiments of the present inventive concept will be described more fully hereinafter with reference to the accompanying drawings. The present inventive concept may, however, be embodied in many different forms and should not be construed as being limited to the embodiments set forth herein. In the drawings, the sizes and relative sizes of layers and regions may be exaggerated for clarity. Like numerals may refer to like elements throughout the specification and drawings.

It will be understood that when an element is referred to as being “connected” or “coupled” to another element, it can be directly connected or coupled to the other element or intervening elements may be present.

As used herein, the singular forms “a,” “an” and “the” are intended to include the plural forms as well, unless the context clearly indicates otherwise.

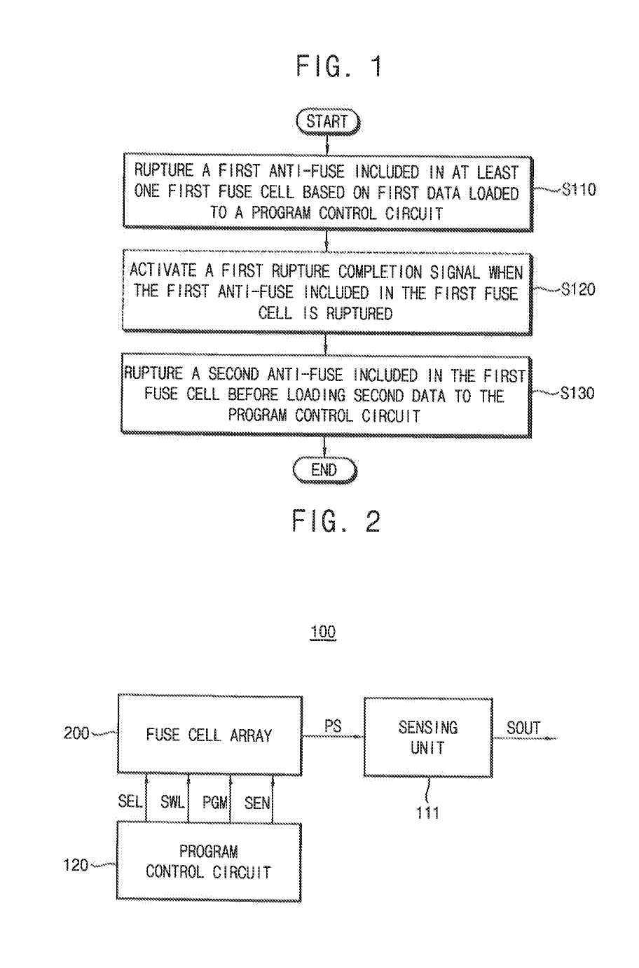

FIG. 1 is a flow chart illustrating a method of programming fuse cells according to an exemplary embodiment of the present inventive concept.

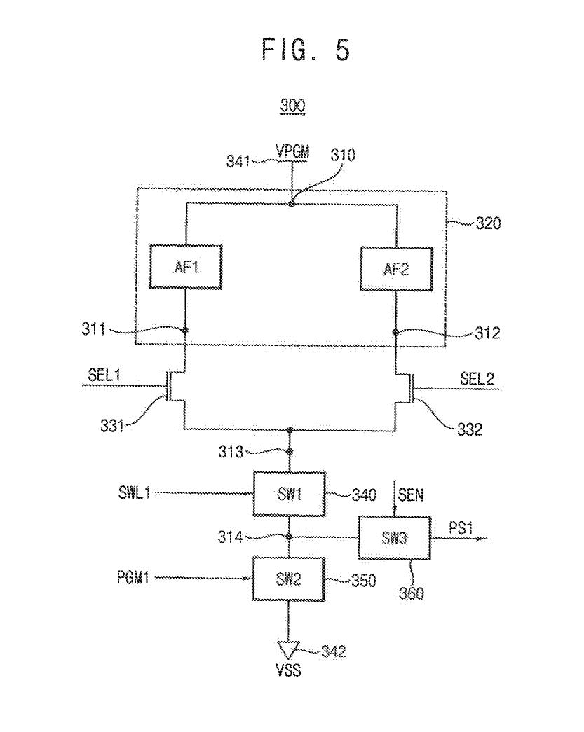

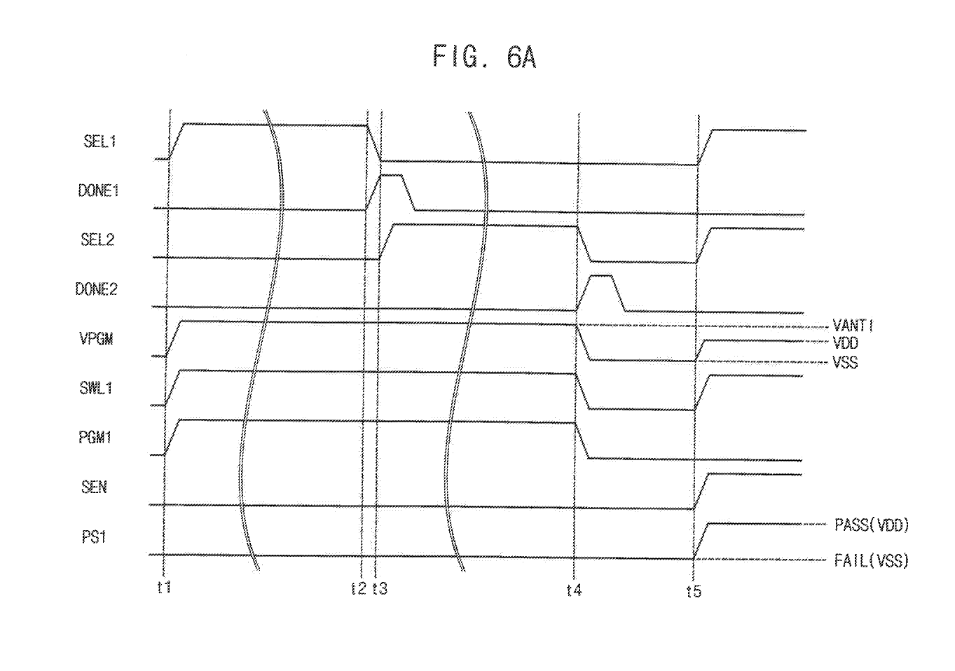

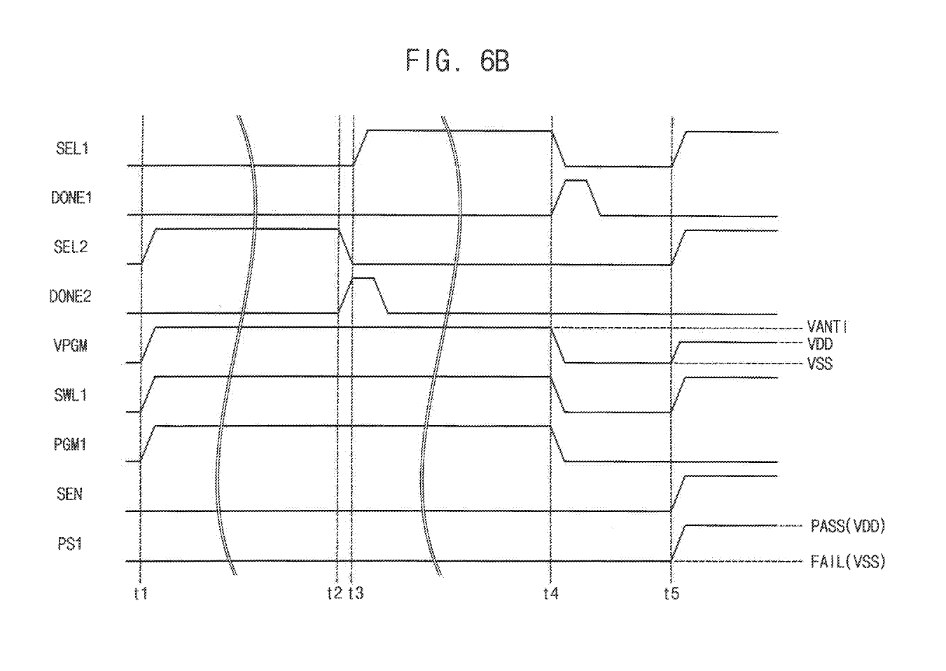

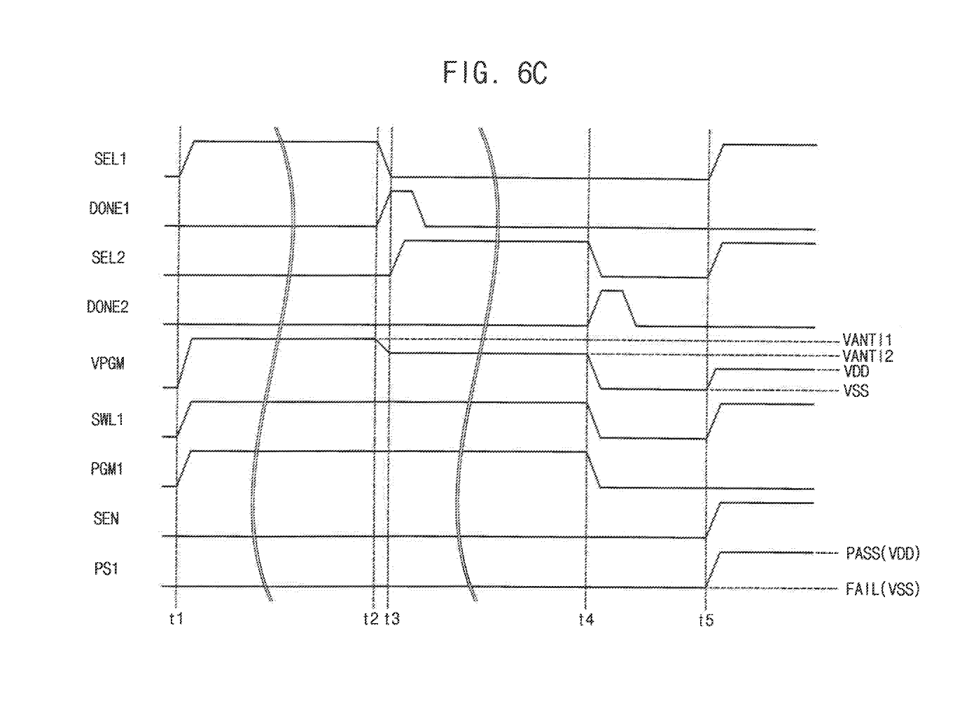

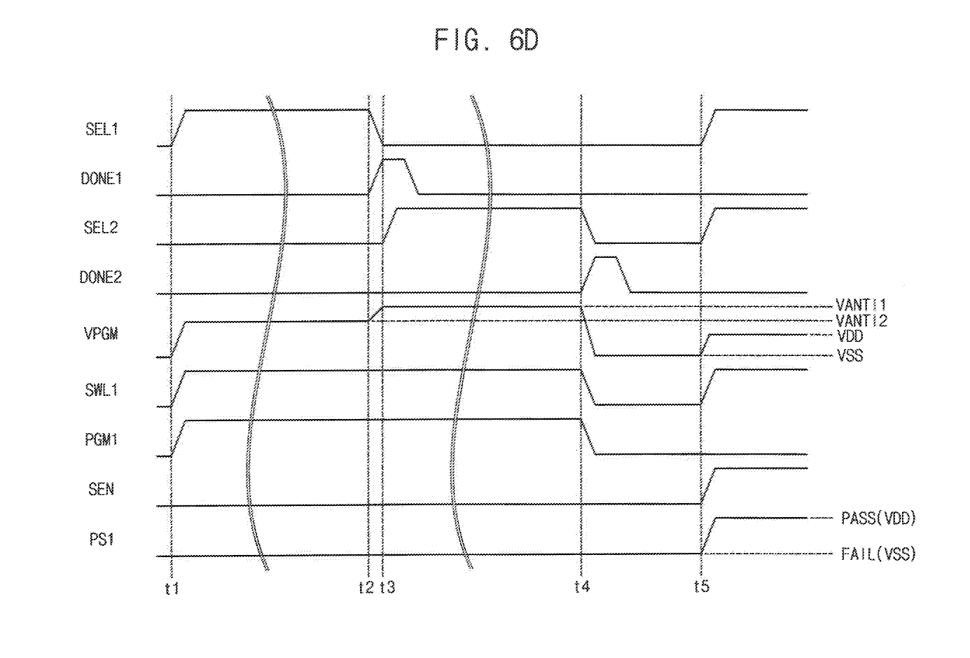

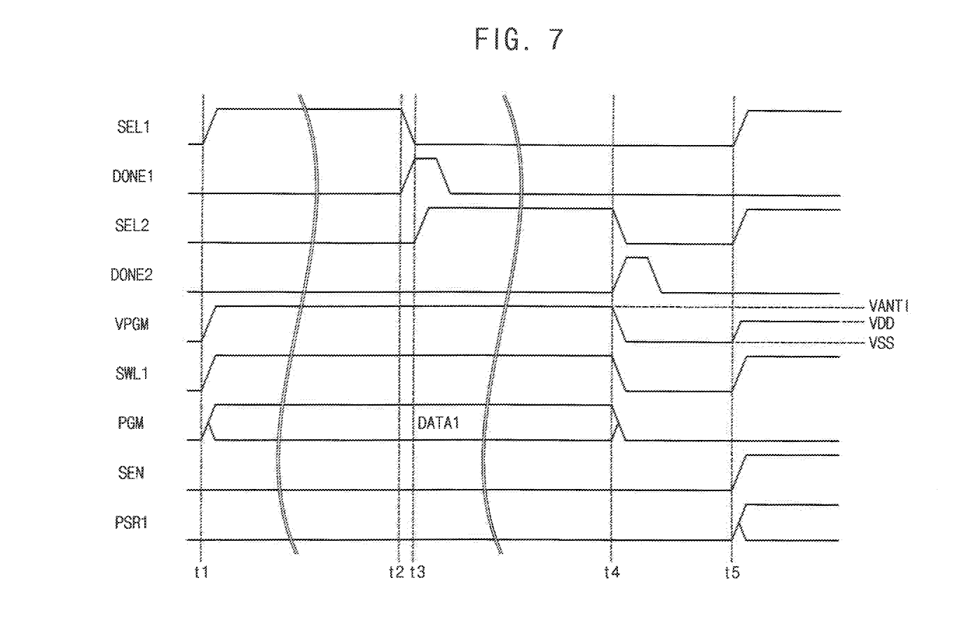

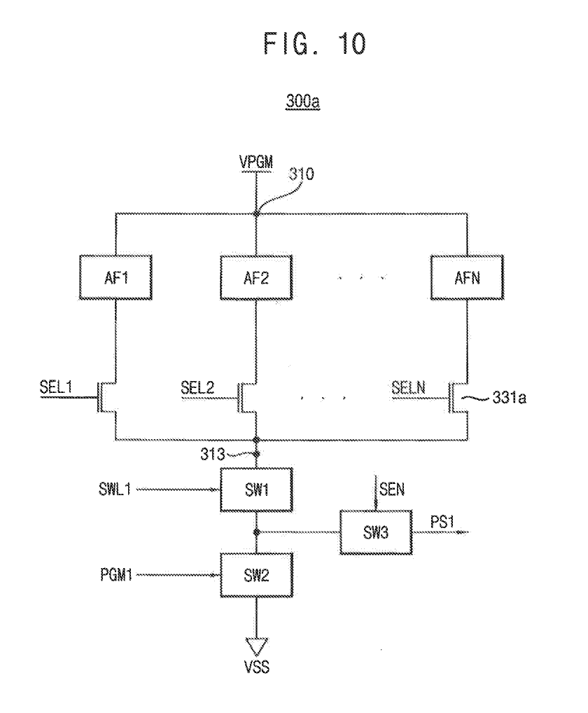

Referring to FIG. 1, to a program fuse cells, each of which includes a first anti-fuse and a second anti-fuse, the first anti-fuse included in at least one first fuse cell is ruptured based on first data loaded to program control circuit (S110). The structure of the fuse cell will be described with reference to FIGS. 5 and 10. The rupturing process of the first anti-fuse will be described with reference to FIGS. 6A and 7.

In an exemplary embodiment of the present inventive concept, a first rupture completion signal may be activated when the first anti-fuse included in the first fuse cell is ruptured (S120).

The second anti-fuse included in the first fuse cell is ruptured before loading second data to the program control circuit, where the second data are for rupturing the first anti-fuse included in at least one second fuse cell or the second anti-fuse included in the second fuse cell (S130). The rupturing of the second anti-fuse (S130) may be executed automatically in response to activation of the first rupture completion signal. The process of rupturing the second anti-fuse will be described with reference to FIGS. 6A, 6B, 6C, 6D and 7.

When the rupturing of the second anti-fuse (S130) and the programming of the first fuse cell is finished, the programming of the second fuse cell is performed.

FIG. 2 is a block diagram illustrating a fuse circuit according to an exemplary embodiment of the present inventive concept.

Referring to FIG. 2, the fuse circuit 100 includes a fuse cell array 200, a program control circuit 120, and a sensing unit 111.

The program control circuit 120 provides a row selection signal SWL, an anti-fuse selection signal (SEL), and a sense enable signal (SEN) to the fuse cell array 200. The program control circuit 120 provides a program signal (PGM) to the fuse cell array 200 based on data loaded to the program control circuit 120.

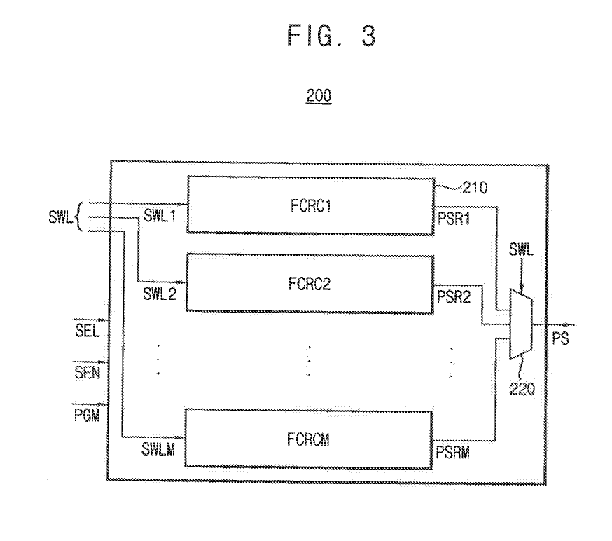

The fuse cell array 200 includes a plurality of fuse cells. The fuse cell array 200 programs the fuse cells based on the row selection signal (SWL), the anti-fuse selection signal (SEL), the program signal (PGM), and the sense enable signal (SEN). The fuse cell array 200 outputs programmed values of the fuse cells as a program output signal (PS) to the sensing unit 111. The fuse cell array 200 will be described with reference to FIG. 3.

The sensing unit 111 outputs a sense output signal (SOUT) based on the program output signal (PS). Whether the fuse cells included in the fuse cell array 200 are programmed may be determined based on the sense output signal (SOUT). Comparators included in the sensing unit 111 generate the sense output signal (SOUT) by comparing the program output signal (PS) and reference voltages.

FIG. 3 is a block diagram illustrating a fuse cell array included in the fuse circuit of FIG. 2 according to an exemplary embodiment of the present inventive concept.

Referring to FIG. 3, the fuse cell array 200 may include fuse cell row circuits (e.g., a first fuse cell row circuit (FCRC1 210), a second fuse cell row circuit (FCRC2), . . . , an M-th fuse cell row circuit (FCRCM)) and a multiplexer 220. The row selection signal (SWL) may include a first row selection signal (SWL1), a second row selection signal (SWL2), and an M-th row selection signal (SWLM).

The first fuse cell row circuit (FCRC1) executes programming based on the first row selection signal (SWL1), the anti-fuse selection signal (SEL), the sense enable signal (SEN), and the program signal (PGM). The first fuse cell row circuit (FCRC1) may output the first program row output signal (PSR1). In the same way, the M-th fuse cell row circuit (FCRCM) executes programming based on the M-th row selection signal (SWLM), the anti-fuse selection signal (SEL), the sense enable signal (SEN), and the program signal (PGM). The M-th fuse cell row circuit (FCRCM) may output the M-th program row output signal (PSRM).

The multiplexer 220 outputs one of the program row output signals (e.g., PSR1, PSR2, PSRM) as the program output signal (PS) based on the fuse cell selection signal (SWL).

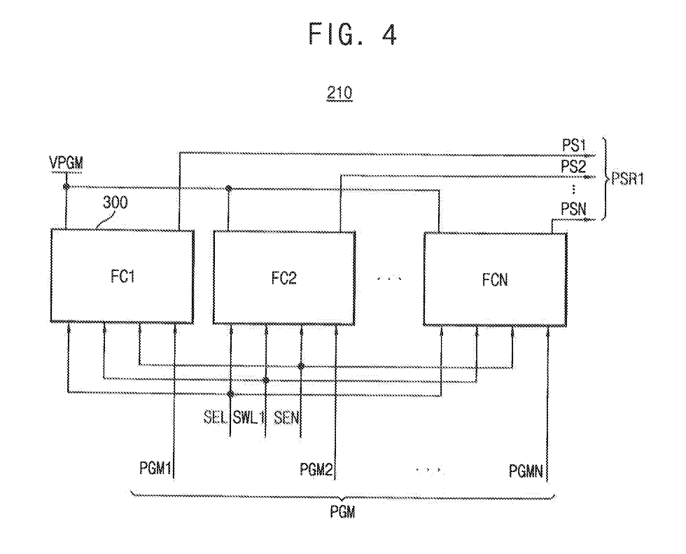

FIG. 4 is a block diagram illustrating a first fuse cell row circuit included in the fuse cell array of FIG. 3 according to an exemplary embodiment of the present inventive concept. Other fuse cell row circuits (e.g., the second fuse cell row circuit FCRC2, the M-th fuse cell row circuit FCRCM) included in the fuse cell array 200 of FIG. 3 may have substantially the same components and interconnections as the first fuse cell row circuit FCRC1 210. Other fuse cell row circuits (e.g., the second fuse cell row circuit (FCRC2), the M-th second fuse cell row circuit (FCRCM)) may receive the row selection signal.

Referring FIG. 4, the first fuse cell row circuit 210 included in the fuse cell array 200 of FIG. 3 includes the plurality of the fuse cells (e.g., FC1 (300) to, FC2, FCN).

Each of the fuse cells (e.g., FC1, FC2, FCN) receives the anti-fuse selection signal (SEL), the first row selection signal (SWL1), the sense enable signal (SEN), the program voltage (VPGM), and each of the program signals (e.g., PGM1, PGM2, PGMN) corresponding to each of the fuse cells (e.g., FC1, FC2, FCN). Anti-fuses included in each of fuse cells (e.g., FC1, FC2, FCN) are ruptured. Each of the fuse cells (e.g., FC1, FC2, FCN) outputs the result of rupturing as each of program output signal (PSR1). The program signals (e.g., PGM1, PGM2, PGMN) may be generated based on data loaded to the program control circuit 120.

FIG. 5 is a block diagram illustrating a fuse cell included in the first fuse cell row circuit of FIG. 4 according to an exemplary embodiment of the present inventive concept.

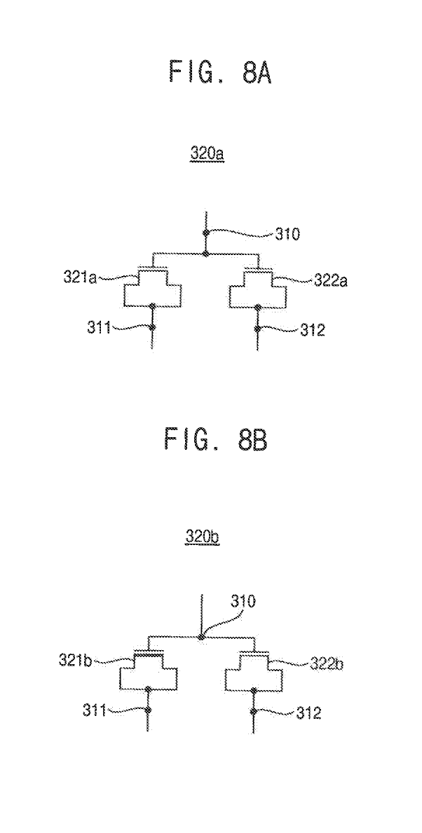

Referring to FIG. 5, a fuse cell 300 includes anti-fuses (e.g., AF1, AF2; 320), program transistors 331, 332, and switches (e.g., SW1, SW2, SW3). The anti-fuses 320 include the first anti-fuse (AF1) and the second anti-fuse (AF2). The structure of the anti-fuses 320 will be described with reference to FIGS. 8A and 8B.

Because the fuse cell 300 of FIG. 5 includes the two parallel anti-fuses (e.g., AF1 and AF2), the anti-fuse selection signal (SEL) of the fuse circuit 100 of FIG. 2, the fuse cell array 200 of FIG. 3 and the fuse cell row circuit 210 of FIG. 4 include a first anti-fuse selection signal (SEL1) and a second anti-fuse selection signal (SEL2).

The program voltage node 341 is electrically connected to a first node 310. Two terminals of the first anti-fuse (AF1) are electrically connected to the first node 310 and a second node 311, respectively. Two terminals of the second anti-fuse (AF2) are connected to the first node 310 and a third node 312, respectively. The first anti-fuse selection signal (SEL1) is provided to a gate terminal of the first program transistor 331. A source terminal of the first program transistor 331 is electrically connected to the second node 311. A drain terminal of the first program transistor 331 is electrically connected to a fourth node 313. The second anti-fuse selection signal (SEL2) is provided to a gate terminal of the second program transistor 332. A source terminal of the second program transistor 332 is electrically connected to the third node 312. A drain terminal of the second program transistor 332 is electrically connected to the fourth node 313. The first switch (SW1) connects or disconnects electrically between the fourth node 313 and a fifth node 314 based on the first row selection signal (SWL1). The second switch (SW2) connects or disconnects electrically between the fifth node 314 and the ground node (VSS) based on the first program signal (PGM1). The third switch (SW3) outputs an electrical signal of the fifth node 314 as a first program output signal (PS1) based on the sense enable signal (SEN).

The first switch (SW1) may be implemented by a first transistor. The first row selection signal (SWL1) is provided to a gate terminal of the first transistor. A source terminal of the first transistor is electrically connected to the fourth node 313. A drain terminal of the first transistor is electrically connected to the fifth node 314. The second switch (SW2) may be implemented by a second transistor. The first program signal (PGM1) is provided to a gate terminal of the second transistor. A source terminal of the second transistor is electrically connected to the fifth node 314. A drain terminal of the second transistor is electrically connected to the ground node (VSS). The third switch (SW3) may be implemented by a third transistor. The sense enable signal (SEN) is provided to a gate terminal of the third transistor. A source terminal of the third transistor is electrically connected to the fifth node 314. The first program output signal (PS1) is provided to a drain terminal of the third transistor.

In addition, program modes of the fuse cell 300 have a first anti-fuse rupturing mode and a second anti-fuse rupturing mode. The first anti-fuse rupturing mode is a case in which the program voltage (VPGM), the first anti-fuse selection signal (SEL1), the first row selection signal (SWL1), and the first program signal (PGM1) are activated. In the first anti-fuse rupturing mode, a first path that interconnects the program voltage node 341, the first node 310, the first anti-fuse (AF1), the second node 311, the turned-on first program transistor 331, the fourth node 313, the first switch (SW1), the fifth node 314, the second switch (SW2), and the ground node 342 is activated. An electrical current on the first path may rupture the first anti-fuse (AF1).

The second anti-fuse rupturing mode is a case in which the program voltage (VPGM), the second anti-fuse selection signal (SEL2), the first row selection signal (SWL1), and the first program signal (PGM1) are activated. In the second anti-fuse rupturing mode, a second path that interconnects the program voltage node 341, the first node 310, the second anti-fuse (AF2), the third node 312, the turned-on second program transistor 332, the fourth node 313, the first switch (SW1), the fifth node 314, the second switch (SW2), and the ground node 342 is activated. An electrical current on the second path may rupture the second anti-fuse (AF2).

A sensing mode is a case in which the program voltage (VPGM), the first anti-fuse selection signal (SEL1), the second anti-fuse selection signal (SEL2), the first row selection signal (SWL1), and the sense enable signal (SEN) are activated. In the sensing mode, a third path and a fourth path are activated. The third path interconnects the program voltage node 341, the first node 310, the first anti-fuse (AF1), the second node 311, the turned-on first program transistor 331, the fourth node 313, the first switch (SW1), the fifth node 314, and the third switch (SW3). The fourth path interconnects the program voltage node 341, the first node 310, the second anti-fuse (AF2), the third node 312, the turned-on second program transistor 332, the fourth node 313, the first switch (SW1), the fifth node 314, and the third switch (SW3). The first program output signal (PS1) may be provided through the third path and the fourth path.

TABLE 1

| | |
|---|---|
| SEPARATED | SIMULTANEOUS |
| RUPTURE | RUPTURE |

| | ANTI- | ANTI- | ANTI- | ANTI- |
|---|---|---|---|---|
| | FUSE 1 | FUSE 2 | FUSE 1 | FUSE 2 |
| MAXIMUM | 46 | 47.6 | 10 | 10.6 |
| CURRENT (uA) | | | | |
| MINIMUM | 9.6 | 13.26 | −0.76 | 0 |
| CURRENT (uA) | | | | |
| MEDIAN | 27.75 | 27.75 | 8.5 | 8.25 |
| CURRENT (uA) | | | | |
| AVERAGE | 28.1425 | 28.2363 | 7.4213 | 7.2770 |
| CURRENT (uA) | | | | |

Referring to Table 1, when the first anti-fuse (AF1) and the second anti-fuse (AF2) are ruptured separately, a voltage between two terminals of the first anti-fuse (AF1) and a voltage between two terminals of the second anti-fuse (AF2) are the same as the program voltage (VPGM). An electrical current on the activated first path including the first anti-fuse (AF1) and an electrical current on the activated second path including the second anti-fuse (AF2) are the same as each other (e.g., 27.75 uA). In this case, since voltage and current provided to the first anti-fuse (AF1) and the second anti-fuse (AF2) are high enough to rupture, the first anti-fuse (AF1) and the second anti-fuse (AF2) may be ruptured without error.

Referring to Table 1, when the first anti-fuse (AF1) and the second anti-fuse (AF2) are ruptured simultaneously, a voltage between two terminals of the first anti-fuse (AF1) and a voltage between two terminals of the second anti-fuse (AF2) are lower than the program voltage (VPGM). An electrical current on the activated first path including the first anti-fuse (AF1) and an electrical current on the activated second path including the second anti-fuse (AF2) ranges from about 7.2 uA to about 7.4 uA. In this case, since voltage and current provided to the first anti-fuse (AF1) and the second anti-fuse (AF2) are not high enough to rupture, the first anti-fuse (AF1) and the second anti-fuse (AF2) might not be ruptured or may be ruptured with error.

FIGS. 6A, 6B, 6C, and 6D are timing diagrams illustrating operations of programming a fuse cell by rupturing sequentially a first anti-fuse and a second anti-fuse according to an exemplary embodiment of the present inventive concept.

Referring to FIG. 6A, the fuse cell 300 retains the first anti-fuse rupturing mode between t1 and t2. At t1, the program control circuit 120 included in the fuse circuit 100 of FIG. 2 activates the first anti-fuse selection signal (SEL1), the program voltage (VPGM), the first row selection signal (SWL1), and the first program signal (PGM1). The first program transistor 331 is turned on in response to the activated first anti-fuse selection signal (SEL1). The two terminals of the first switch (SW1), the fourth node 313, and the fifth node 314 are electrically connected in response to the activated first row selection signal (SWL1). The two terminals of the second switch (SW2), the fifth node 314, and the ground node (VSS) are electrically connected in response to the activated first program signal (PGM1). For example, when the first path is activated and the program voltage (VPGM) activated as a relatively high voltage (VANTI) such as 5V˜7V, e.g., 6.5V, is provided between the two terminals of the first anti-fuse (AF1), and when a sufficient time (e.g., from t1 to t2) for rupturing is elapsed, the first anti-fuse (AF1) may be ruptured without error. The resistance between two terminals of the first anti-fuse (AF1) before rupturing may be several hundreds kΩ to several MΩ. The resistance between the two terminals of the first anti-fuse (AF1) after rupturing may be about 1 kΩ.

When a sufficient time (e.g., from t1 to t2) to rupture the anti-fuse is elapsed, the program control circuit 120 inactivates the first anti-fuse selection signal (SEL1) at t2 and activates a first anti-fuse rupture completion signal (DONE1). During an interval between t2 and t3, the program voltage (VPGM), the first row selection signal (SWL1), and the first program signal (PGM1) retain the activated states.

During an interval between t3 and t4, the fuse cell 300 retains the second anti-fuse rupturing mode. The first anti-fuse rupture completion signal (DONE1) is activated at t3. The program control circuit 120 activates the second anti-fuse selection signal (SEL2) automatically without loading the second data besides the first data to the program control circuit 120 at t3. During an interval between t3 and t4, the program voltage (VPGM), the first row selection signal (SWL), and the first program signal (PGM1) retain the activated states. The second program transistor 332 is turned on in response to the activated second anti-fuse selection signal (SEL2). Two terminals of the first switch (SW1), the fourth node 313, and the fifth node 314 are electrically connected in response to the activated first row selection signal (SWL1). Two terminals of the second switch (SW2), the fifth node 314, and the ground node (VSS) are electrically connected in response to the activated first program signal (PGM1). For example, when the second path is activated and the program voltage (VPGM) activated as a relatively high voltage (VANTI) is provided to the two terminals of the second anti-fuse (AF2), and when a sufficient time (e.g., from t3 to t4) is elapsed, the second anti-fuse (AF2) may be ruptured.

When a sufficient time (e.g., from t3 to t4) to rupture the anti-fuse is elapsed, the program control circuit 120 inactivates the second anti-fuse selection signal (SEL2) at t4 and activates a second anti-fuse rupture completion signal (DONE2).

The fuse cell 300 retains the sensing mode after t5. At t5, the program control circuit 120 activates the first anti-fuse selection signal (SEL1), the second anti-fuse selection signal (SEL2), the first row selection signal (SWL), and the sense enable signal (SEN). The first program transistor 331 is turned on in response to the activated first anti-fuse selection signal (SEL1). The second program transistor 332 is turned on in response to the activated second anti-fuse selection signal (SEL2). The two terminals of the first switch (SW1), the fourth node 313, and the fifth node 314 are electrically connected in response to the activated first row selection signal (SWL1). The two terminals of the third switch (SW3) are electrically connected in response to the sense enable signal (SEN). The first program output signal (PS1), which is generated by the activated third path and the activated fourth path, is provided to the sensing unit 111 included in the fuse circuit 100 of FIG. 2. FIG. 6A shows a case in which a voltage level of VDD is provided as the program voltage (VPGM) in the sensing mode. The first program output signal (PS1) has the voltage level of VDD when the first anti-fuse (AF1) or the second anti-fuse (AF2) is ruptured without error. The first program output signal (PS1) has a ground voltage level (e.g., a voltage level at the ground node (VSS)) and a program fault is generated when the first anti-fuse (AF1) and the second anti-fuse (AF2) are ruptured with error. In the sensing mode, various voltage levels in the vicinity of the voltage level of VDD may be provided as the program voltage (VPGM) to determine whether the fuse cell 300 is programmed with error or not.

Referring FIG. 6B, the fuse cell 300 retains the second anti-fuse rupturing mode between t1 and t2. Operations of the fuse cell 300 in the second anti-fuse rupturing mode may be the same as the operations of the fuse cell 300 in the second anti-fuse rupturing mode described with reference to FIG. 6A.

When a sufficient time (e.g., from t1 to t2) to rupture the anti-fuse is elapsed, the program control circuit 120 inactivates the second anti-fuse selection signal (SEL2) at t2 and activates the second anti-fuse rupture completion signal (DONE2). During an interval between t2 and t3, the program voltage (VPGM), the first row selection signal (SWL1), and the first program signal (PGM1) retains the activated states.

During an interval between t3 and t4, the fuse cell 300 retains the first anti-fuse rupturing mode without loading the second data besides the first data to the program control circuit 120. Operations of the fuse cell 300 in the first anti-fuse rupturing mode are may be the same as the operations of the fuse cell 300 in the first anti-fuse rupturing mode described with reference to FIG. 6A.

When a sufficient time (e.g., from t3 to t4) to rupture the anti-fuse is elapsed, the program control circuit 120 inactivates the first anti-fuse selection signal (SEL1) at t4 and activates the first anti-fuse rupture completion signal (DONE1).

The fuse cell 300 retains the sensing mode after t5. Operations of the fuse cell 300 in the sensing mode may be the same as the operations of the fuse cell 300 in the sensing mode described with reference to FIG. 6A.

FIG. 6C is the same as FIG. 6A except that the program voltage (VPGM) is a first high voltage (VANTI1) in the first anti-fuse rupturing mode between t1 and t2 and the program voltage (VPGM) is a second high voltage (VANTI2) which is lower than the first high voltage (VANTI 1) in the second anti-fuse rupturing mode between t3 and t4.

FIG. 6D is the same as FIG. 6a except that the program voltage (VPGM) is the second high voltage (VANTI2) in the first anti-fuse rupturing mode between t1 and t2 and the program voltage (VPGM) is the first high voltage (VANTI1) in the second anti-fuse rupturing mode between t3 and t4.

FIG. 7 is a timing diagram illustrating an operation of programming the first fuse cell row circuit of FIG. 4 according to an exemplary embodiment of the present inventive concept.

Referring to FIG. 7, the fuse cells (e.g., FC1, FC2, FCN) included in the first fuse cell row circuit 210 of FIG. 4 retain the first anti-fuse rupturing mode between t1 and t2. The anti-fuse selection signal (SEL) of FIG. 4 includes the first anti-fuse selection signal (SEL1) and the second anti-fuse selection signal (SEL2). At t1, the program control circuit 120 included in the fuse circuit 100 of FIG. 2 activates the first anti-fuse selection signal (SEL1), the program voltage (VPGM), and the first row selection signal (SWL1) which are commonly inputted to the fuse cells (e.g., FC1, FC2, FCN). The program control circuit 120 provides the first data (DATA1) for programming as the program signal (PGM) to the first fuse cell row circuit 210. The first program transistor 331 included to each of the fuse cells (e.g., FC1, FC2, FCN) is turned on in response to the activated first anti-fuse selection signal (SEL1). The two terminals of the first switch (SW1) included in each of the fuse cells (e.g., FC1, FC2, FCN) are electrically connected in response to the activated first row selection signal (SWL1). The two terminals of the second switch (SW2) included in each of the fuse cells (e.g., FC1, FC2, FCN) are electrically connected in response to each of the activated program signal (PGM). For example, when the program voltage (VPGM) that is activated as a high voltage (VANTI) is provided between the two terminals of the first anti-fuse (AF1) included in each of the fuse cells (e.g., FC1, FC2, FCN), and when a sufficient time (e.g., from t1 to t2) for rupturing is elapsed, the first anti-fuse (AF1) included in each of the fuse cells (e.g., FC1, FC2, FCN) may be ruptured without error.

When a sufficient time (e.g., from t1 to t2) to rupture the anti-fuse is elapsed, the program control circuit 120 inactivates the first anti-fuse selection signal (SEL1) at t2 and activates the first anti-fuse rupture completion signal (DONE1). During an interval between t2 and t3, the program voltage (VPGM) and the first row selection signal (SWL1) retain the activated states, and the program signal (PGM) retains the first data (DATA1).

During an interval between t3 and t4, the fuse cells (e.g., FC1, FC2, and FCN) retain the second anti-fuse rupturing mode. The first anti-fuse rupture completion signal (DONE1) is activated at t3. The program control circuit 120 activates the second anti-fuse selection signal (SEL2) automatically without loading the second data besides the first data (DATA1) to the program control circuit 120 at t3. During an interval between t3 and t4, the program voltage (VPGM) and the first row selection signal (SWL1) retains the activated states, and the program signal (PGM) retains the first data (DATA1). The second program transistor 332 included in each of the fuse cells (e.g., FC1, FC2, FCN) is turned on in response to the activated second anti-fuse selection signal (SEL2). The two terminals of the first switch (SW1) included in each of the fuse cells (e.g., FC1, FC2, FCN) are electrically connected in response to the activated first row selection signal (SWL 1). The two terminals of the second switch (SW2) included in each of the fuse cells (e.g., FC1, FC2, FCN) are electrically connected or disconnected in response to each of the activated program signal (PGM). When the second path is activated and the program voltage (VPGM) that is activated as a high voltage (VANTI) is provided to the two terminals of the second anti-fuse (AF2) included in each of the fuse cells (e.g., FC1, FC2, FCN), and when a sufficient time (e.g., from t3 to t4) is elapsed, the second anti-fuse (AF2) included in each of the fuse cells (e.g., FC1, FC2, FCN) may be ruptured.

When a sufficient time (e.g., from t3 to t4) to rupture the anti-fuse is elapsed, the program control circuit 120 inactivates the second anti-fuse selection signal (SEL2) at t4 and activates the second anti-fuse rupture completion signal (DONE2).

The fuse cells (e.g., FC1, FC2, and FCN) retain the sensing mode after t5. At t5, the program control circuit 120 activates the first anti-fuse selection signal (SEL1), the second anti-fuse selection signal (SEL2), the first row selection signal (SWL1), and the sense enable signal (SEN). The first program transistor 331 included in each of the fuse cells (e.g., FC1, FC2, FCN) is turned on in response to the activated first anti-fuse selection signal (SEL1). The second program transistor 332 included in each of the fuse cells (e.g., FC1, FC2, FCN) is turned on in response to the activated second anti-fuse selection signal (SEL2). The two terminals of the first switch (SW1) included in each of the fuse cells (e.g., FC1, FC2, FCN) are electrically connected in response to the activated first row selection signal (SWL). The two terminals of the third switch (SW3) included in each of the fuse cells (e.g., FC1, FC2, FCN) are electrically connected in response to the sense enable signal (SEN). The first program row output signal (PSR1), which is generated by the activated third path and the activated fourth path, is provided to the sensing unit 111 included in the fuse circuit 100 of FIG. 2. When the first anti-fuse cell (AF1) or the second anti-fuse cell (AF2) included in each of the fuse cells (e.g., FC1, FC2, FCN) is ruptured without error, the first program row output signal (PSR1) has the first data (DATA1) and the first fuse cell row circuit 210 is programmed without error. When the first anti-fuse (AF1) included in at least one fuse cell of the fuse cells (e.g., FC1, FC2, FCN) and the second anti-fuse (AF2) included in the at least one fuse cell are not ruptured, the first program row output signal (PSR1) does not have the first data (DATA1) and the first fuse cell row circuit 210 is programmed with error.

FIGS. 8A and 8B are circuit diagrams illustrating anti-fuses included in the fuse cell of FIG. 5 according to an exemplary embodiment of the present inventive concept.

Referring to FIG. 8A, the anti-fuses 320a included in the fuse cell 300 of FIG. 5 includes a first transistor 321a and a second transistor 322a. In an exemplary embodiment of the present inventive concept, the first transistor 321a may be an enhancement type MOS transistor. A gate terminal of the first transistor 321a may be electrically connected to the first node 310. Source and drain terminals of the first transistor 321a may be electrically connected to the second node 311. The second transistor 322a may be an enhancement type MOS transistor. A gate of the second transistor 322a may be electrically connected to the first node 310. Source and drain terminals of the second transistor 322a may be electrically connected to the third node 312. In an exemplary embodiment of the present inventive concept, the first transistor 321a and the second transistor 322a may be depletion type MOS transistors. The operation of programming the fuse cell 300 including the first transistor 321a and the second transistor 322a was described with reference to FIGS. 6A and 6B.

Referring to FIG. 8B, the anti-fuses 320b include a first transistor 321b and a second transistor 322b. In an exemplary embodiment of the present inventive concept, the first transistor 321b may be a depletion type MOS transistor. A gate terminal of the first transistor 321b may be electrically connected to the first node 310. Source and drain terminals of the first transistor 321b may be electrically connected to the second node 311. The second transistor 322b may be an enhancement type MOS transistor. A gate terminal of the second transistor 322b may be electrically connected to the first node 310. Source and drain terminals of the second transistor 322b may be electrically connected to the third node 321.

The first transistor 321b which is a depletion type MOS transistor and the second transistor 322b which is an enhancement type MOS transistor may have gate oxide layers (or insulating layers) which have substantially the same thickness, and the first transistor 321b and the second transistors 322b may have substantially the same channel width and the same channel length as each other. In addition, the first transistor 321b, which is a depletion type MOS transistor, includes a channel which is previously formed, and thus, the first transistor 321b, which is a depletion type MOS transistor, has a gate oxide layer which is ruptured at a lower level of a rupturing voltage than the second transistor 321b which is an enhancement type MOS transistor.

Operations of programming the fuse cell 300 including the first transistor 321b and the second transistor 322b were described with reference to FIG. 6D in which a rupturing voltage of the first transistor 321b is a second high voltage (VANTI2) and a rupturing voltage of the second transistor 322b is a first high voltage (VANTI1) which is higher than the second high voltage (VANTI2).

In an exemplary embodiment of the present inventive concept, the first transistor 321b may be an enhancement type MOS transistor and the second transistor 322b may be a depletion type MOS transistor. In this case, operations of programming the fuse cell 300 including the first transistor 321b and the second transistor 322b were described with reference to FIG. 6C in which the rupturing voltage of the first transistor 321b is the first high voltage (VANTI1) and the rupturing voltage of the second transistor 322b is the second high voltage (VANTI2) which is lower than the first high voltage (VANTI 1).

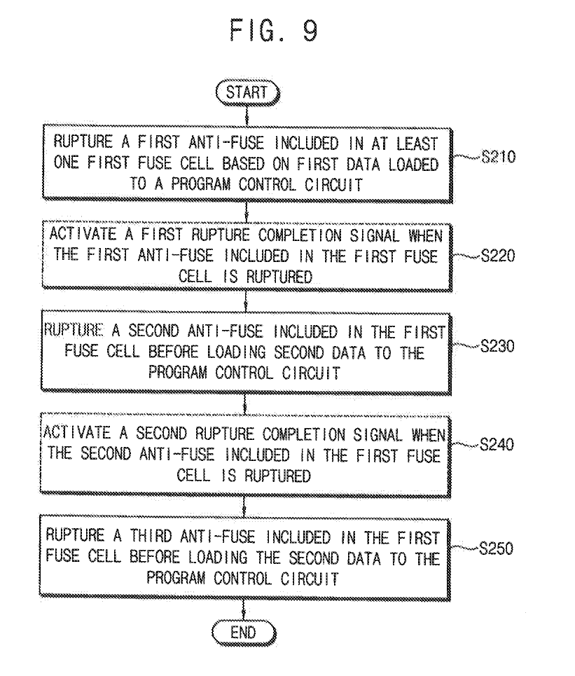

FIG. 9 is a flow chart illustrating a method of programming fuse cells according to an exemplary embodiment of the present inventive concept.

Referring to FIG. 9, to perform programming on the fuse cells including the first anti-fuse, the second anti-fuse, and the third anti-fuse, the first anti-fuse included in at least one first fuse cell is ruptured based on first data loaded to the program control circuit (S210). The structure of the fuse cell including the first anti-fuse, the second anti-fuse, and the third anti-fuse will be described with reference to FIG. 10.

In an exemplary embodiment of the present inventive concept, a first rupture completion signal may be activated when the first anti-fuse included in the first fuse cell is ruptured (S220).

The second anti-fuse included in the first fuse cell is ruptured before loading second data to the program control circuit to rupture the first anti-fuse included in at least one second fuse cell or the second anti-fuse included in the second fuse cell (S230). The rupturing of the second anti-fuse may be executed in response to the activation of the first rupture completion signal.

In an exemplary embodiment of the present inventive concept, a second rupture completion signal is activated when the second anti-fuse included in the first fuse cell is ruptured (S240).

The third anti-fuse included in the first fuse cell is ruptured before loading the second data to the program control circuit to rupture the first anti-fuse included in the second fuse cell, the second anti-fuse included in the second fuse cell, or the third anti-fuse included in the second fuse cell (S250).

When the rupturing of the second anti-fuse (S250) is completed, the programming of the first fuse cell is finished according to the first data (DATA1), and then the programming of the second fuse cell is performed.

The rupturing of the first anti-fuse included in at least one first fuse cell (S210), the activating of the first rupture completion signal when the first anti-fuse included in the first fuse cell is ruptured (S220), the rupturing of the second anti-fuse included in the first fuse cell before loading the second data to the program control circuit (S230), the activating of the second rupture completion signal when the second anti-fuse included in the first fuse cell is ruptured (S240), and the rupturing of the third anti-fuse included in the first fuse cell before loading the second data to the program control circuit (S250) may be understood with reference to FIG. 1.

FIG. 10 is a circuit diagram illustrating fuse cells included in the first fuse cell row circuit of FIG. 4 according to an exemplary embodiment of the present inventive concept.

Referring to FIG. 10, the fuse cell 300a uses the fuse cell 300 of FIG. 5. as a basic structure and further may include N-th circuits. A terminal of the N-th circuit is electrically connected to the first node 310 and the other terminal of the N-th circuit is electrically connected to the fourth node 313. The N-th circuit includes the N-th anti-fuse (AFN) and the N-th program transistor 331a. A terminal of the N-th anti-fuse (AFN) is electrically connected to the first node 310 and the other terminal of the N-th anti-fuse (AFN) is electrically connected to a source terminal of the N-th program transistor 331a. The N-th anti-fuse selection signal (SELN) is provided to a gate terminal of the N-th program transistor 331a. A drain terminal of the N-th program transistor 331a is electrically connected to the fourth node 313. The anti-fuses (e.g., AF1, AF2, and AFN) may have substantially the same rupturing voltage. The anti-fuses (e.g., AF1, AF2, and AFN) may have different rupturing voltages from each other. Although it is illustrated that the fuse cell 300a of FIG. 10 further includes the N-th circuit in addition to the fuse cell 300 of FIG. 5, the present inventive concept is not limited to thereto. For example, a circuit having similar structure and function to each of the circuits (e.g., the first circuit, the second circuit, and the N-th circuit) may be included in the fuse cell 300a.

Since the fuse cell 300a is programmed without error when at least one anti-fuse of the anti-fuses (e.g., AF1, AF2, and AFN) is ruptured without error, a probability of programming the fuse cell 300a without error is higher than a probability of programming the fuse cell 300 without error.

Operations of programming a fuse cell may be understood with reference to FIGS. 6A, 6B, 6C, and 6D.

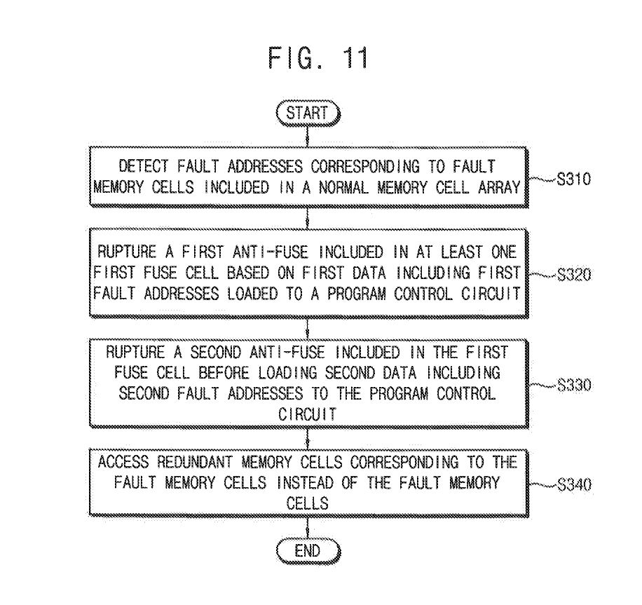

FIG. 11 is a flow chart illustrating a method of repairing a memory device according to an exemplary embodiment of the present inventive concept. In general, a semiconductor memory device may include redundant memory cells to prepare for a case in which fault memory cells are generated. In a testing procedure, the fault addresses according to the fault memory cells may be detected and thus, the fault addresses may be programmed to the fuse cells including the anti-fuses. When a memory access request is generated in runtime and an address to access is determined to be the same as one of the fault addresses, redundant memory cells corresponding to the one of the fault memory cells may be accessed instead of that fault memory cell. The detecting of the fault addresses, the programming of the fuse cells using the fault addresses, and the accessing of the redundant memory cells instead of the fault memory cell are referred to as a memory cell repair process.

Referring to FIG. 11, a memory device includes fuse cells having a first anti-fuse and a second anti-fuse. To repair the memory device, fault addresses corresponding to fault memory cells included in a normal memory cell array are detected (S310).

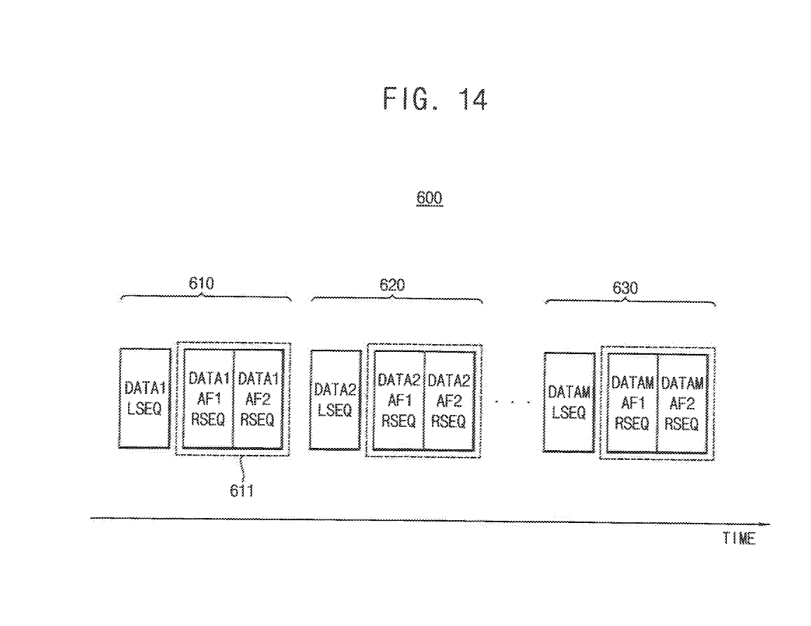

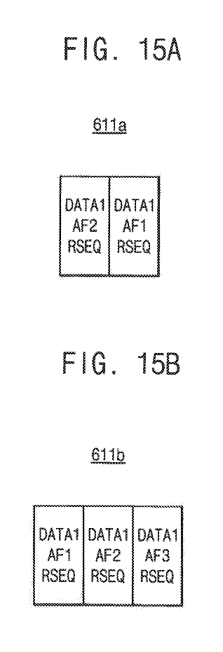

The first anti-fuse included in at least one first fuse cell is ruptured based on first data including first fault addresses loaded to a program control circuit (S320). The second anti-fuse included in the first fuse cell is ruptured before loading second data including second fault addresses to the program control circuit to rupture the first anti-fuse included in at least one second fuse cell or the second anti-fuse included in the second fuse cell (S330). The rupturing of the first anti-fuse included in at least one first fuse cell (S320) and the rupturing of the second anti-fuse included in the first fuse cell before loading second data including second fault addresses to the program control circuit (S330) will be described with reference to FIGS. 14 and 15A.

For example, the fuse cells may be used to store signatures of the fault memory cells.

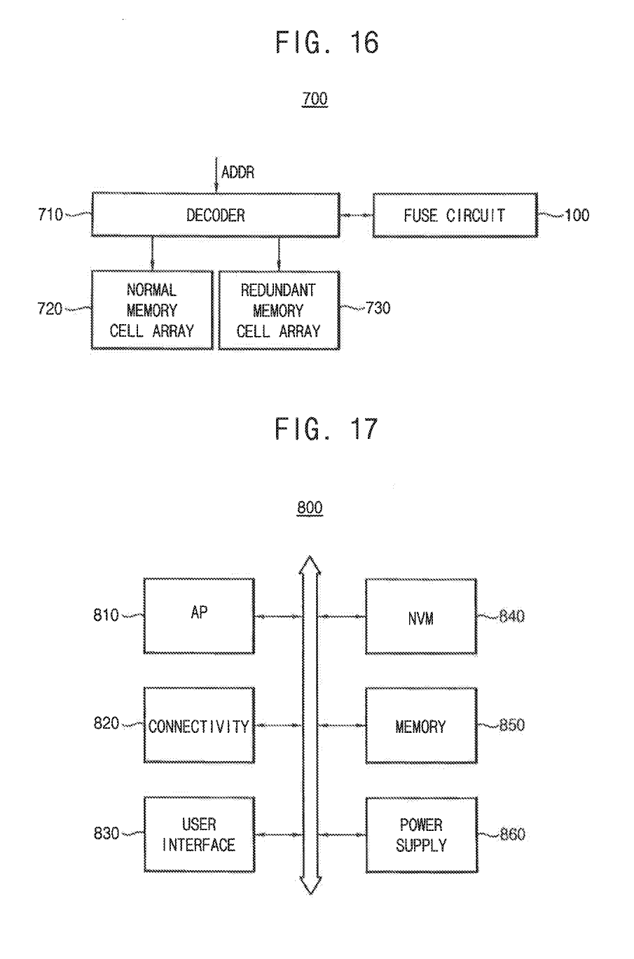

Redundant memory cells corresponding to the fault memory cells are accessed instead of the fault memory cells when a memory access request to the fault addresses is generated during runtime after the first anti-fuse of the fuse cells and the second anti-fuse of the fuse cells are ruptured (S340). The accessing of redundant memory cells corresponding to the fault memory cells instead of the fault memory cells (S340) will be described with reference to FIG. 16.

When the accessing of redundant memory cells corresponding to the fault memory cells instead of the fault memory cells (S340) is completed, the repairing of the memory device including the fault memory cells is completed.

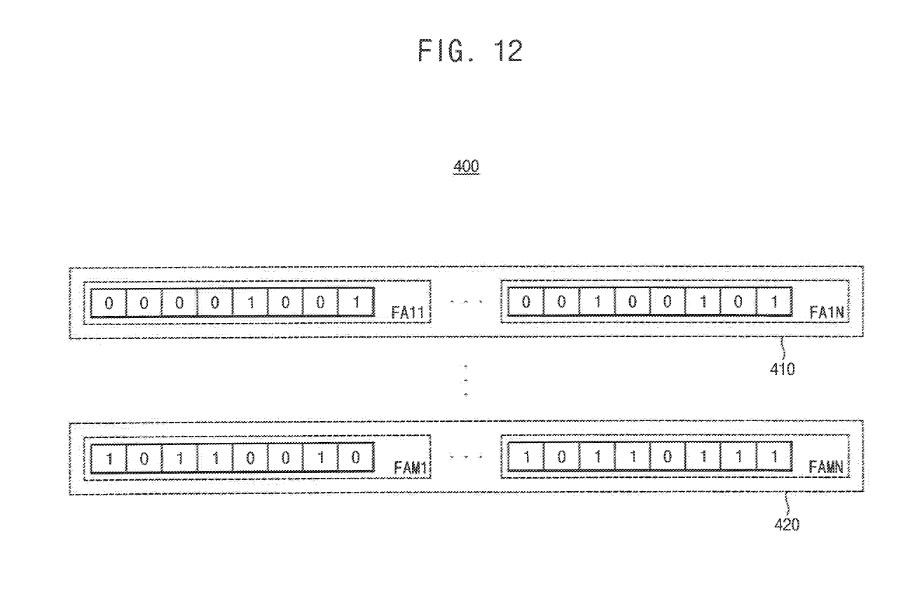

FIG. 12 is a diagram illustrating data which is programmed to the fuse cell array of FIG. 3 according to an exemplary embodiment of the present inventive concept.

Referring to FIG. 12, a data group 400 which is programmed to the fuse cell array 200 of FIG. 3 may include first data 410 to M-th data 420. The first data 410 may include N fault addresses (e.g., first fault address (FA11) to the second fault address (FA1N)). The M-th data 420 may include N fault addresses (e.g., third fault address (FAM1) to the fourth fault address (FAMN)). In an exemplary embodiment of the present inventive concept, each of the fault addresses (e.g., FA11, FA1N, FAM1, and FAMN) may have 8 bits. The fault addresses are addresses corresponding to the fault memory cells in the normal memory cell array.

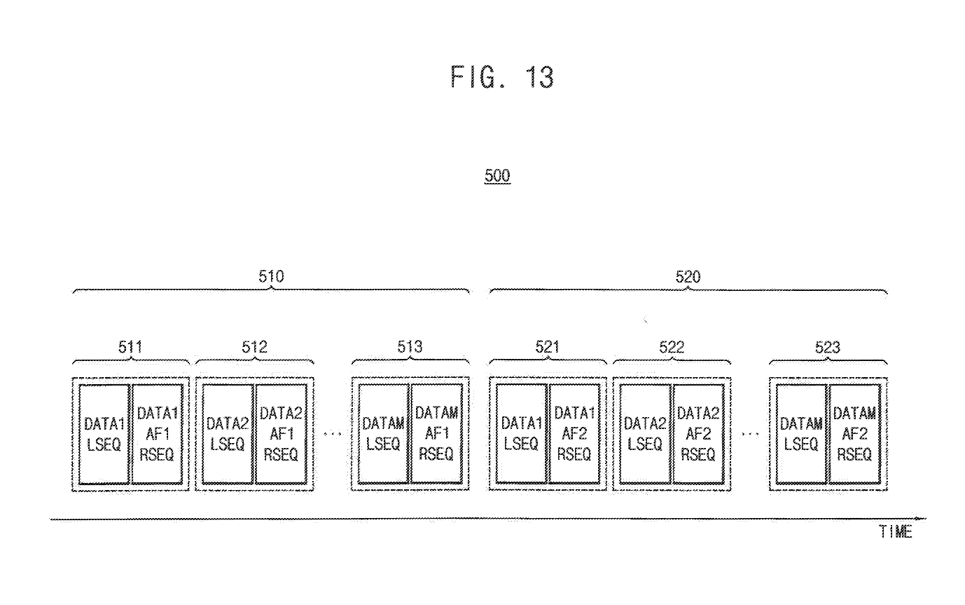

FIG. 13 is a diagram illustrating a programming sequence as a comparison example.

Referring to FIG. 13, a programming sequence 500 of the fuse cell array 200 of FIG. 3 may include a first programming sequence 510 and a second programming sequence 520. The first programming sequence 510 may include a first anti-fuse rupturing sequence 511 of the first fuse cell row circuit (FCRC1), a first anti-fuse rupturing sequence 512 of the second fuse cell row circuit (FCRC2), and a first anti-fuse rupturing sequence 513 of the M-th fuse cell row circuit (FCRCM). The second programming sequence 520 may include a second anti-fuse rupturing sequence 521 of the first fuse cell row circuit (FCRC1), a second anti-fuse rupturing 20) sequence 522 of the second fuse cell row circuit (FCRC2), and a second anti-fuse rupturing sequence 523 of the M-th fuse cell row circuit (FCRCM). The first anti-fuse rupturing sequence 511 of the first fuse cell row circuit (FCRC1) includes a first sequence (DATA1 LSEQ) of loading the first data (DATA1) to the program control circuit 120 included in the fuse circuit 100 of FIG. 2 and a second sequence (DATA1 AF1 RSEQ) of rupturing the first anti-fuses included in the first fuse cell row circuit (FCRC1) based on the first data (DATA1). The first anti-fuse rupturing sequence 512 of the second fuse cell row circuit (FCRC2), the first anti-fuse rupturing sequence 513 of the M-th fuse cell row circuit (FCRCM), the second anti-fuse rupturing sequence 521 of the first fuse cell row circuit (FCRC1), the second anti-fuse rupturing sequence 522 of the second fuse cell row circuit (FCRC2), and the second anti-fuse rupturing sequence 523 of the M-th fuse cell row circuit (FCRCM) may be understood based on the description of the first anti-fuse rupturing sequence 521 of the first fuse cell row circuit (FCRC1).

In the first sequence (DATA1 AF1 LSEQ), the first row selection signal (SWL1), and the program signal (PGM) are activated based on the first data (DATA 1), the first anti-fuse selection signal (SEL1) included in the anti-fuse selection signal (SEL) is activated, and the second anti-fuse selection signal (SEL2) included in anti-fuse selection signal (SEL) is inactivated. When the first data (DATA1) is provided to the first fuse cell row circuit (FCRC1) through the program signal (PGM), each of the fuse cells (e.g., FC1, FC2, FCN) included in the first fuse cell row circuit (FCRC1) is ruptured in response to each of the program signals (e.g., PGM1, PGM2, PGMN) corresponding to each of the fuse cells (e.g., FC1, FC2, FCN).

In the case that the fuse cell array 200 is programmed according to the programming sequence 500, the same data may be loaded to the program control circuit 120 twice for programming the fuse cell row circuit.

FIG. 14 is a diagram illustrating a programming sequence according to an exemplary embodiment of the present inventive concept.

Referring to FIG. 14, a programming sequence 600 of the fuse cell array 200 of FIG. 3 according to an exemplary embodiment of the present inventive concept includes a programming sequence 610 of the first fuse cell row circuit (FCRC1), a programming sequence 620 of the second fuse cell row circuit (FCRC2), and a programming sequence 630 of the M-th fuse cell row circuit (FCRCM).

The programming sequence 610 of the first fuse cell row circuit (FCRC1) includes a first sequence (DATA1 LSEQ) of loading the first data (DATA1) to the program control circuit (120), a second sequence (DATA1 AF1 RSEQ) of rupturing the first anti-fuses included in the first fuse cell row circuit (FCRC1) based on the first data (DATA1), and a third sequence (DATA1 AF2 RSEQ) rupturing the second anti-fuses included in the first fuse cell row circuit (FCRC1) based on the first data (DATA1). The programming sequence 620 of the second fuse cell row circuit (FCRC2) and the programming sequence 630 of the M-th fuse cell row circuit (FCRCM) may be understood based on the description of the programming sequence 610 of the first fuse cell row circuit (FCRC1). A partial programming sequence 611 of the first fuse cell row circuit includes a second sequence (DATA1 AF1 RSEQ) and a third sequence (DATA1 AF2 RSEQ).

In the case that the fuse cell array 200 is programmed according to the programming sequence 600 (according to an exemplary embodiment of the present inventive concept), the first sequence (DATA1 LSEQ) is executed before the second sequence (DATA1 AF1 RSEQ), the second sequence (DATA1 AF2 RSEQ) is executed before the third sequence (DATA1 AF2 RSEQ), and the third sequence (DATA1 AF2 RSEQ) is executed before a fourth sequence (DATA2 LSEQ). The third sequence (DATA1 AF2 RSEQ) is executed without loading the second data (DATA2) to the program control circuit 120. Relationships between the other sequences of FIG. 14 may be understood based on the previous description.

Unlike the case using the programming sequence 500 to program the fuse cell array 200 in which the same data is loaded to the program control circuit 120 twice for programming a fuse cell row circuit when the fuse cell array 200 is programmed according to the programming sequence 600 (according to an exemplary embodiment of the present inventive concept), data is loaded to the program control circuit 120 just one time for programming a fuse cell row circuit, and thus, a programming time of the fuse cell array 200 may be reduced.

FIGS. 15A and 15B are diagrams illustrating partial programming sequences included in the programming sequence of FIG. 14 according to an exemplary embodiment of the present inventive concept.

Referring to FIG. 15A, a partial programming sequence 611a of the first fuse cell row circuit (FCRC1) having the fuse cell 300 of FIG. 5 includes a first sequence (DATA1 AF1 RSEQ) of rupturing the first anti-fuses included in the first fuse cell row circuit based on the first data (DATA1) and a second sequence (DATA1 AF2 RSEQ) of rupturing the second anti-fuses included in the first fuse cell row circuit (FCRC1) based on the first data (DATA1). In an exemplary embodiment of the present inventive concept, the first sequence (DATA1 AF1 RSEQ) may be executed before the second sequence (DATA1 AF2 RSEQ). In an exemplary embodiment of the present inventive concept, the first sequence (DATA1 AF1 RSEQ) may be executed after the second sequence (DATA1 AF2 RSEQ).

Referring to FIG. 15B, a partial programming sequence 611b of the first fuse cell row circuit (FCRC1) having the fuse cell 300a of FIG. 10 includes the first sequence (DATA1 AF1 RSEQ) of rupturing the first anti-fuses included in the first fuse cell row circuit (FCRC1) based on the first data (DATA1), the second sequence (DATA1 AF2 RSEQ) of rupturing the second anti-fuses included in the first fuse cell row circuit (FCRC1) based on the first data (DATA1), and the third sequence (DATA1 AF3 RSEQ) of rupturing the third anti-fuses included in the first fuse cell row circuit (FCRC1) based on the first data (DATA1). In an exemplary embodiment of the present inventive concept, the first sequence (DATA1 AF1 RSEQ) may be executed before the second sequence (DATA1 AF2 RSEQ) and the second sequence (DATA1 AF2 RSEQ) may be executed before the third sequence (DATA1 AF3 RSEQ).

FIG. 16 is a block diagram illustrating a semiconductor memory device including the fuse circuit according to an exemplary embodiment of the present inventive concept.

Referring to FIG. 16, a semiconductor memory device 700 includes an address decoder 710, a normal memory cell array 720, a redundant memory cell array 730, and the fuse circuit 100.

The normal memory cell array 720 includes a plurality of normal memory cells and the redundant memory cell array 730 includes a plurality of redundant memory cells.

The fuse circuit 100 programs the fault addresses corresponding to the fault memory cells to the fuse cells included in the fuse circuit 100, and outputs a sense output signal (SOUT) denoting whether the fuse cells are programmed or not.

The address decoder 710 accesses selectively either the normal memory cell array 720 or the redundant memory cell array 730 based on an address signal (ADDR) and the sense output signal (SOUT). The address decoder 710 may include a row decoder that selects a word line or a column decoder that selects a bit line. The address decoder 710 may include both the row decoder and the column decoder. The fuse circuit 100 may repair the fault memory cell in the unit of the row or the column.

FIG. 17 is a diagram illustrating a mobile system applying the semiconductor memory device according to an exemplary embodiment of the present inventive concept.

Referring to FIG. 17, a mobile system 800 includes an application processor (AP) 810, a connectivity unit 820, a memory device 850, a nonvolatile memory (NVM) device 840, a user interface 830, and a power supply 860. In an exemplary embodiment of the present inventive concept, the mobile system 800 may be a mobile phone, a smart phone, a personal digital assistant (PDA), a portable multimedia player (PMP), a digital camera, a music player, a portable game console, a navigation system, etc.

The application processor 810 may execute applications, such as a web browser, a game application, a video player, etc. In an exemplary embodiment of the present inventive concept, the application processor 810 may include a single core or multiple cores. For example, the application processor 810 may be a multi-core processor, such as a dual-core processor, a quad-core processor, a hexa-core processor, or the like. The application processor 810 may include an internal or an external cache memory.

The connectivity unit 820 may perform a wired or a wireless communication with an external device. For example, the connectivity unit 820 may perform Ethernet communication, near field communication (NFC), radio frequency identification (RFID) communication, mobile telecommunication, memory card communication, universal serial bus (USB) communication, etc. In an exemplary embodiment of the present inventive concept, the connectivity unit 820 may include a baseband chipset that supports communications, such as global system for mobile communications (GSM), general packet radio service (GPRS), wideband code division multiple access (WCDMA), high speed downlink/uplink packet access (HSxPA), etc.

The memory device 850 may store data processed by the application processor 810, or may operate as a working memory. Each of memory cells included in the memory device 850 may include a write transistor, a read transistor, and a metal oxide semiconductor (MOS) capacitor. The write transistor may include a gate electrode coupled to a write word line, a first electrode coupled to a write bit line, and a second electrode coupled to a storage node. The read transistor may include a gate electrode coupled to the storage node, a first electrode coupled to a read word line, and a second electrode coupled to a read bit line. The MOS capacitor may include a gate electrode coupled to the storage node and a lower electrode coupled to a synchronization control line. A synchronization pulse signal may be applied to the lower electrode of the MOS capacitor in synchronization with a write word line signal in a write operation and may be applied to the lower electrode of the MOS capacitor in synchronization with a read word line signal in a read operation. Thus, a coupling effect may occur at the storage node through the MOS capacitor in response to the synchronization pulse signal and a data retention time of the memory cell included in the memory device 850 may increase. As such, the memory device 850 may have a longer data retention time than a dynamic random access memory (DRAM). In addition, the memory device 850 may a higher density than a static random access memory (SRAM). For example, the memory device 850 may be embodied with the memory device 700 of FIG. 16. The memory device 850 may have substantially the same structure and operation as the memory device 700 of FIG. 16 which is described above with reference to FIGS. 1 to 15. Thus, a detailed description of the memory device 850 will be omitted.

The nonvolatile memory device 840 may store a boot image for booting the mobile system 800. For example, the nonvolatile memory device 840 may be an electrically erasable programmable read-only memory (EEPROM), a flash memory, a phase change random access memory (PRAM), a resistance random access memory (RRAM), a nano floating gate memory (NFGM), a polymer random access memory (PoRAM), a magnetic random access memory (MRAM), a ferroelectric random access memory (FRAM), etc.

The user interface 830 may include at least one input device such as a keypad, a touch screen, etc., and may include at least one output device such as a speaker, a display device, etc. The power supply 860 may supply a power supply voltage to the mobile system 800.

In an exemplary embodiment of the present inventive concept, the mobile system 800 may further include an image processor and/or a storage device, such as a memory card, a solid state drive (SSD), a hard disk drive (HDD), a CD-ROM, etc.

In an exemplary embodiment of the present inventive concept, the mobile system 800 and/or components of the mobile system 800 may be packaged in various forms, such as a package on package (PoP), ball grid arrays (BGAs), chip scale packages (CSPs), a plastic leaded chip carrier (PLCC), a plastic dual in-line package (PDIP), a die in waffle pack, a die in wafer form, chip on board (COB), a ceramic dual in-line package (CERDIP), a plastic metric quad flat pack (MQFP), a thin quad flat pack (TQFP), a small outline integrated circuit (SOIC), a shrink small outline package (SSOP), a thin small outline package (TSOP), a system in package (SIP), a multi chip package (MCP), a wafer-level fabricated package (WFP), or wafer-level processed stack package (WSP).

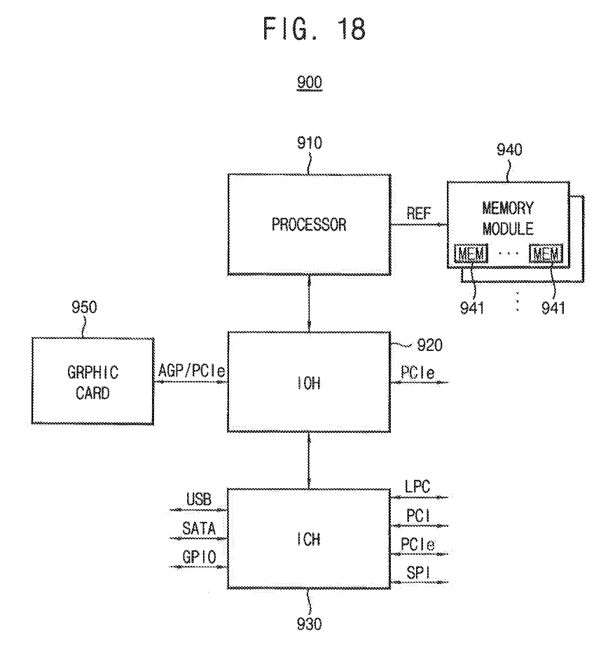

FIG. 18 is a diagram illustrating a computing system applying the semiconductor memory device according to an exemplary embodiment of the present inventive concept.

Referring to FIG. 18, a computing system 900 includes a processor 910, an input/output hub (IOH) 920, an input/output controller hub (ICH) 930, at least one memory module 940, and a graphics card 950. In an exemplary embodiment of the present inventive concept, the computing system 900 may be a personal computer (PC), a server computer, a workstation, a laptop computer, a mobile phone, a smart phone, a personal digital assistant (PDA), a portable multimedia player (PMP), a digital camera, a digital television, a set-top box, a music player, a portable game console, a navigation system, etc.

The processor 910 may perform various computing functions, such as executing specific software for performing specific calculations or tasks. For example, the processor 910 may be a microprocessor, a central process unit (CPU), a digital signal processor, or the like. In an exemplary embodiment of the present inventive concept, the processor 910 may include a single core or multiple cores. For example, the processor 910 may be a multi-core processor, such as a dual-core processor, a quad-core processor, a hexa-core processor, etc. Although FIG. 18 illustrates the computing system 900 including one processor 910, the computing system 900 may include a plurality of processors in an exemplary embodiment of the present inventive concept.

The processor 910 may include a memory controller for controlling operations of a memory module 940. The memory controller included in the processor 910 may be referred to as an integrated memory controller (IMC). A memory interface between the memory controller and the memory module 940 may be implemented with a single channel including a plurality of signal lines, or may be implemented with multiple channels. At least one memory module 940 may be coupled to each of the multiple channels. In an exemplary embodiment of the present inventive concept, the memory controller may be located inside the input/output hub 920. The input/output hub 920 including the memory controller may be referred to as memory controller hub (MCH).

The memory module 940 may include a plurality of memory devices MEM 941 that stores data provided from the memory controller. Each of memory cells included in the memory device 941 may include a write transistor, a read transistor, and a metal oxide semiconductor (MOS) capacitor. The write transistor may include a gate electrode coupled to a write word line, a first electrode coupled to a write bit line and a second electrode coupled to a storage node. The read transistor may include a gate electrode coupled to the storage node, a first electrode coupled to a read word line and a second electrode coupled to a read bit line. The MOS capacitor may include a gate electrode coupled to the storage node and a lower electrode coupled to a synchronization control line. A synchronization pulse signal may be applied to the lower electrode of the MOS capacitor in synchronization with a write word line signal in a write operation and may be applied to the lower electrode of the MOS capacitor in synchronization with a read word line signal in a read operation. Thus, a coupling effect may occur at the storage node through the MOS capacitor in response to the synchronization pulse signal and thus, a data retention time of the memory cell included in the memory device 941 may increase. As such, the memory device 941 may have a longer data retention time than a dynamic random access memory (DRAM). In addition, the memory device 941 may have a higher density than a static random access memory (SRAM). For example, the memory device 941 may be embodied with the memory device 700 of FIG. 16. The memory device 941 may have substantially the same structure and operation as the memory device 700 which is described above with reference to FIGS. 1 to 15. Thus, a detailed description of the memory device 941 will be omitted.

The input/output hub 920 may manage data transfer between the processor 910 and other devices, such as the graphics card 950. The input/output hub 920 may be coupled to the processor 910 via various interfaces. For example, the interface between the processor 910 and the input/output hub 920 may be a front side bus (FSB), a system bus, a HyperTransport, a lightning data transport (LDT), a QuickPath interconnect (QPI), a common system interface (CSI), etc. The input/output hub 920 may provide various interfaces with the devices. For example, the input/output hub 920 may provide an accelerated graphics port (AGP) interface, a peripheral component interface-express (PCIe), a communications streaming architecture (CSA) interface, etc. Although FIG. 18 illustrates the computing system 900 including one input/output hub 920, the computing system 900 may include a plurality of input/output hubs in an exemplary embodiment of the present inventive concept.

The graphics card 950 may be coupled to the input/output hub 920 via AGP or PCIe. The graphics card 950 may control a display device for displaying an image. The graphics card 950 may include an internal processor for processing image data and an internal memory device. In an exemplary embodiment of the present inventive concept, the input/output hub 920 may include an internal graphics device along with or instead of the graphics card 950 outside the graphics card 950. The graphics device included in the input/output hub 920 may be referred to as integrated graphics. Further, the input/output hub 920 including the internal memory controller and the internal graphics device may be referred to as a graphics and memory controller hub (GMCH).

The input/output controller hub 930 may perform data buffering and interface arbitration to efficiently operate various system interfaces. The input/output controller hub 930 may be coupled to the input/output hub 920 via an internal bus, such as a direct media interface (DMI), a hub interface, an enterprise Southbridge interface (ESI), PCIe, etc.

The input/output controller hub 930 may provide various interfaces with peripheral devices. For example, the input/output controller hub 930 may provide a universal serial bus (USB) port, a serial advanced technology attachment (SATA) port, a general purpose input/output (GPIO), a low pin count (LPC) bus, a serial peripheral interface (SPI), PCI, PCIe, etc.

In an exemplary embodiment of the present inventive concept, the processor 910, the input/output hub 920, and the input/output controller hub 930 may be implemented as separate chipsets or separate integrated circuits. In an exemplary embodiment of the present inventive concept, at least two of the processor 910, the input/output hub 920, and the input/output controller hub 930 may be implemented as a single chipset.

The present inventive concept may be used to program fuse cells and to repair a semiconductor memory device using the programmed fuse cells including a plurality of anti-fuses.

As described above, the method of programming fuse cells according to an exemplary embodiment of the present inventive concept may reduce a data loading time of the program control circuit. The data loading time is included in a programming time of the fuse cells to sequentially rupture the parallel anti-fuses included in each of the fuse cells.

The method of repairing a memory device may increase the productivity of the memory device by reducing the repairing time of the memory device.

Although the present inventive concept has been described with reference to exemplary embodiments thereof, it will be understood by those of ordinary skill in the art that various modifications in form and details may be made therein without departing from the spirit and scope of the present inventive concept as defined by the following claims.

What is claimed is:

1. A method of programming a plurality of fuse cells including a first fuse cell and a second fuse cell, wherein each of the first and second fuse cells includes a first anti-fuse and a second anti-fuse, the method comprising:
rupturing the first anti-fuse of the first fuse cell based on first data loaded to a program control circuit; and
rupturing the second anti-fuse of the first fuse cell before loading second data to the program control circuit, the second data being for rupturing the first anti-fuse of the second fuse cell or the second anti-fuse of the second fuse cell.

2. The method of claim 1, further comprising:
activating a first rupture completion signal when the rupturing of the first anti-fuse of the first fuse cell is completed.

3. The method of claim 2, wherein the rupturing of the second anti-fuse of the first fuse cell is executed in response to the first rupture completion signal.

4. The method of claim 2, wherein each of the first and second fuse cells further includes a third anti-fuse.

5. The method of claim 4, further comprising:
rupturing the third anti-fuse of the first fuse cell before loading the second data to the program control circuit to rupture the first anti-fuse of the second fuse cell or the second anti-fuse of the second fuse cell or the third anti-fuse of the second fuse cell.

6. The method of claim 5, further comprising:
activating a second rupture completion signal when the rupturing of the second anti-fuse of the first fuse cell is completed.

7. The method of claim 6, wherein the rupturing of the third anti-fuse is executed in response to the second rupture completion signal.

8. The method of claim 1, wherein the first data and the second data include fault addresses corresponding to fault memory cells in a normal memory cell array.

9. The method of claim 8, wherein the fuse cells is used to store signatures of the fault memory cells.

10. The method of claim 1, wherein the first anti-fuse and the second anti-fuse in each of the first and second fuse cells have substantially the same rupture voltage level.

11. The method of claim 1, wherein the first anti-fuse and the second anti-fuse included in each of the first and second fuse cells have different rupture voltage levels from each other.

12. A method of repairing a memory device including a plurality of fuse cells including a first fuse cell and a second fuse cell, wherein each of the first and second fuse cells includes a first anti-fuse and a second anti-fuse, the method comprising:
detecting fault addresses corresponding to fault memory cells in a normal memory cell array;
rupturing the first anti-fuse of the first fuse cell based on first data loaded to a program control circuit, wherein the first data includes at least one first fault address among the fault addresses;
rupturing the second anti-fuse of the first fuse cell before loading second data to the program control circuit, wherein the second data is for rupturing the first anti-fuse of the second fuse cell or the second anti-fuse of the second fuse cell and the second data includes at least one second fault address among the fault addresses; and
accessing redundant memory cells corresponding to the fault memory cells when a memory access request to the fault addresses is generated during runtime and the first and second anti-fuses of the plurality of fuse cells are ruptured.

13. A fuse circuit, comprising:
a fuse cell array; and
a program control circuit configured to provide a plurality of signals to the fuse cell array,
wherein the fuse cell array comprises:
a plurality of fuse row circuits, each of which is configured to perform programming on a plurality of fuse cells in each of the fuse row circuits based on the signals provided by the program control circuit,
wherein each of the fuse cells includes a first anti-fuse and a second anti-fuse,
wherein sequential rupturing of the first and second anti-fuses of the first fuse cell included in the fuse cell array is performed based on first data loaded to the program control circuit before loading second data to the program control circuit, the second data being for rupturing the first or the second anti-fuses of the second fuse cell included in the fuse cell array.

14. The fuse circuit of claim 13, wherein the signals provided by the program control circuit includes a first row selection signal, a first anti-fuse selection signal, a second anti-fuse selection signal, a sense enable signal, or a program signal.

15. The fuse circuit of claim 13, further comprising:
a sensing unit configured to output a sense output signal based on a program output signal provided by the fuse cell array, wherein the program output signal includes programmed values of the plurality of fuse cells in each of the fuse row circuits.

16. The fuse circuit of claim 13, wherein the fuse cell array further comprises a multiplexer configured to select one of outputs from the plurality of fuse row circuits.

17. The fuse circuit of claim 14, wherein each of the fuse cells further comprises a first program transistor, and a second program transistor,
wherein one node of the first anti-fuse and one node of the second anti-fuse are connected to a first node,
wherein the first node is connected to the driving voltage (VDD) node,
wherein the other node of the first anti-fuse is connected to a source terminal of the first program transistor and the other node of the second anti-fuse is connected to a source terminal of the second program transistor,
wherein a drain terminal of the first program transistor and a drain terminal of the second program transistor are connected to a second node,
wherein the first anti-fuse selection signal is input to a gate terminal of the first program transistor to control the first program transistor, and the second anti-fuse selection signal is input to a gate terminal of the second program transistor to control the second program transistor.

18. The fuse circuit of claim 17, wherein each of the fuse cells further comprises a first switch, a second switch, and third switch,
wherein one node of the first switch is connected to the second node and the other node of the first switch is connected to a third node,
wherein one node of the second switch and one node of the third switch are connected to the third node, and the other node of the second switch is connected to the ground node.

19. The fuse circuit of claim 18, wherein the first anti-fuse is ruptured based on the first anti-fuse selection signal and the second anti-fuse is ruptured based on the second anti-fuse selection signal.

20. The fuse circuit of claim 18, wherein the first anti-fuse and the second anti-fuse are ruptured based on the first row selection signal.
